(19) United States
(12) Patent Application Publication
(10) Pub. No.: US 2013/0106401 A1
(43) Pub. Date: May 2, 2013

(54) OSCILLOSCOPE PROBE COMPRISING STATUS INDICATOR

(71) Applicants: Kenneth W. JOHNSON, Colorado Springs, CO (US); Michael T. MCTIGUE, Colorado Springs, CO (US)

(72) Inventors: Kenneth W. JOHNSON, Colorado Springs, CO (US); Michael T. MCTIGUE, Colorado Springs, CO (US)

(73) Assignee: AGILENT TECHNOLOGIES, INC., Loveland, CO (US)

(21) Appl. No.: 13/285,171

(22) Filed: Oct. 31, 2011

(51) Int. Cl. G01R 13/20

(52) U.S. Cl. 324/121 R

(57) ABSTRACT

A system comprises an oscilloscope and an oscilloscope probe having a status indicator. The status indicator is located on a probe head of the oscilloscope probe and is configured to convey information to a user to indicate at least one characteristic of the signal. In certain embodiments, the status indicator comprises a light or a screen to convey signal related information to the user.

### BACKGROUND

An oscilloscope is a type of electronic test instrument that allows a user to probe and observe electronic signals. This is typically accomplished by the user identifying a probe target on a circuit or device, and then manually placing a tip of an oscilloscope probe in contact with the probe target. The probe target typically comprises a conductive portion of a circuit or device, such as a via, pad, leg, or wire. Once in contact with the probe target, the oscilloscope probe transmits a signal apparent at the probe target from the probe tip to an oscilloscope. The oscilloscope then processes and displays the signal to the user to allow observation of various signal characteristics, such as wave shape, frequency, amplitude, distortion, and so on.

The use of the oscilloscope probe in conjunction with the oscilloscope typically requires dexterity and ability to multi-task on the part of the user. For example, the user generally must be able to manually maintain the probe tip in contact with the probe target while looking at signal characteristics on the oscilloscope display. At the same time, the user may be further required to manually actuate controls on the oscilloscope to capture a desired waveform, focus on a particular area of a signal, or switch between observing different signal characteristics. Performing all of these tasks simultaneously can make it difficult for the user to maintain contact between the probe tip and the probe target, especially when the probe target is located in a very fine-pitched, small, tight, dense circuit board.

What is needed, therefore, are techniques to make it easier for a user to simultaneously measure and observe signals through the use of an oscilloscope probe.

### SUMMARY

In accordance with a representative embodiment, a system comprises: an oscilloscope probe comprising a probe head having a probe tip and configured to transmit a signal from the probe tip to an oscilloscope; and a status indicator located on the probe head and configured to convey information to a user to indicate at least one characteristic of the signal.

In accordance with another representative embodiment, a method of operating an oscilloscope probe comprising a probe head having a probe tip and configured to transmit a signal from the probe tip to an oscilloscope is disclosed. The method comprises: analyzing the signal to determine at least one characteristic of the signal; and controlling a status indicator located on the probe head to indicate the at least one characteristic to a user.

### BRIEF DESCRIPTION OF THE DRAWINGS

The described embodiments are best understood from the following detailed description when read with the accompanying drawing figures. Wherever applicable and practical, like reference numerals refer to like elements.

FIG. 1 is a diagram of an oscilloscope according to an example embodiment.

FIG. 2 is a diagram of an oscilloscope probe according to an example embodiment.

FIGS. 3A and 3B are diagrams of an oscilloscope probe according to another example embodiment.

FIG. 4 is a diagram of an oscilloscope probe according to still another example embodiment.

FIG. 5 is a flowchart illustrating a method of operating an oscilloscope probe according to an example embodiment.

FIG. 6 is a flowchart illustrating a method of operating an oscilloscope probe according to another example embodiment.

### DETAILED DESCRIPTION

In the following detailed description, for purposes of explanation and not limitation, representative embodiments disclosing specific details are set forth in order to provide a thorough understanding of the present teachings. However, it will be apparent to one having ordinary skill in the art having had the benefit of the present disclosure that other embodiments according to the present teachings that depart from the specific details disclosed herein remain within the scope of the appended claims. Moreover, descriptions of well-known apparatuses and methods may be omitted so as to not obscure the description of the example embodiments. Such methods and apparatuses are clearly within the scope of the present teachings.

The terminology used herein is for purposes of describing particular embodiments only, and is not intended to be limiting. The defined terms are in addition to the technical and scientific meanings of the defined terms as commonly understood and accepted in the technical field of the present teachings.

As used in the specification and appended claims, the terms ‘a’, ‘an’ and ‘the’ include both singular and plural referents, unless the context clearly dictates otherwise. Thus, for example, ‘a device’ includes one device and plural devices.

As used in the specification and appended claims, and in addition to their ordinary meanings, the terms ‘substantial’ or ‘substantially’ mean to within acceptable limits or degree.

The representative embodiments relate generally to oscilloscope probes and methods of operating oscilloscope probes. In certain embodiments, an oscilloscope probe comprises a probe head containing a status indicator that conveys information relating to one or more characteristics of a signal being probed. For example, the status indicator can be used to indicate whether the signal is an alternating current (AC) signal or whether it is a direct current (DC) signal above a certain threshold voltage. The status indicator can also be used to convey information relating to the status of an oscilloscope, such as whether it is running, stopped, awaiting a trigger, or whether the oscilloscope probe is connected to a particular channel.

The status indicator can make it easier for a user to use the oscilloscope probe in conjunction with an oscilloscope. For example, it can allow a user to determine whether a particular signal is being detected or to identify certain signal characteristics without requiring the user to look at an oscilloscope screen. In other words, it can reduce the amount of multi-tasking required to use the oscilloscope probe. Consequently, the status indicator can lead to more efficient and accurate use of the oscilloscope probe.

The status indicator can take various alternative forms in different embodiments. For example, in some embodiments, the status indicator comprises a light such as a light emitting diode (LED). The light can be operated in a variety of ways to indicate different signal characteristics or oscilloscope characteristics. For instance, it can be maintained in a persistent “on” or “off” state to indicate whether a detected signal is toggling, whether it has an amplitude above a threshold voltage, or whether it falls within a particular frequency range. Alternatively, the light can be controlled to have a “flashing” state or a “dimmed” state to represent other signal characteristics.

In certain alternative embodiments, the status indicator comprises a display screen such as a liquid crystal display (LCD). The display screen can be mounted on the probe head and used to present graphical information indicating one or more signal characteristics or oscilloscope characteristics. For example, it can present numbers, letters, or other graphical symbols to indicate measurement values. Moreover, the display screen can be used in conjunction with a button or some other interface on the probe head, to make the display screen show different signal characteristics or oscilloscope characteristics. In other words, the button or interface can allow a user to cycle through different display modes. The display screen can also be used in conjunction with a multimeter chip in order capture and display a variety of signal characteristics such as frequency, amplitude, phase, and so on.

The status indicator can also be used in conjunction with a switch or other interface on the probe head to initiate one or more functions of the oscilloscope. For example, the switch can be pushed by the user to initiate a stop function of the oscilloscope. This switch can be convenient, for example, when the user notices that the status indicator indicates a particular signal characteristic and wishes to capture the signal while the characteristic is present.

Although certain embodiments may be described with respect to specific types of oscilloscopes or oscilloscope probes, these embodiments are not to be construed as limiting. In general, the described embodiments can be applied to virtually any type oscilloscope probe, including single-ended and differential oscilloscope probes, current probes, passive and active probes, and so on. Moreover, although certain embodiments are described with respect to oscilloscope probes having specific types of probe tips, such as those requiring a user to maintain a steady hand, these embodiments can be modified to use other types of probe tips such as those including grabbers and so on.

Passive probes are perhaps the most widely used type of oscilloscope probe. They are also generally the most rugged and economical. There are typically no active components such as transistors or amplifiers in the probe, and therefore passive probes do not need to be powered. Accordingly, in embodiments where a status indicator is connected to a probe head of a passive probe, the status indicator may be substantially self-contained such that it does not draw power from other components of the probe.

Active probes typically contain a small, active amplifier built into the probe head near the probe tip. This arrangement makes it possible to keep the probe input capacitance very low, which can result in high input impedance on high frequencies. Moreover, active probes tend to have the best overall combination of resistive and capacitive loading. With such low loading, active probes can be used on high-impedance circuits that would be seriously loaded by typical passive probes. As such, active probes can be the least intrusive of available probe types. Because active probes contain active components, such as the active amplifier, they typically include power connectors and other features that can be used to power or control a status indicator.

A differential probe is an active probe with two inputs, one positive and one negative, as well as a separate ground lead. In some embodiments, it typically drives a single-terminated 50-Ω cable to transmit its output to one oscilloscope channel. The output signal is proportional to the difference between the voltages appearing at the two inputs. A differential probe can be used to look at signals that are referenced to each other instead of earth ground and to look at small signals in the presence of large DC offsets or other common mode signals such as power line noise.

A current probe senses current flowing through a conductor and converts it to a voltage that can be viewed and measured on an oscilloscope. Certain current probes use a hybrid technology that includes a Hall-effect sensor, which senses the DC current, and a current transformer, which senses the AC current. Using split core construction, the current probe easily clips on and off of a conductor, making it unnecessary to make an electrical connection to the circuit. Measurement bandwidths from DC to 100 MHz are available.

The above and other types of oscilloscope probes can be used to implement various embodiments as described below, or any of numerous variants of those embodiments.

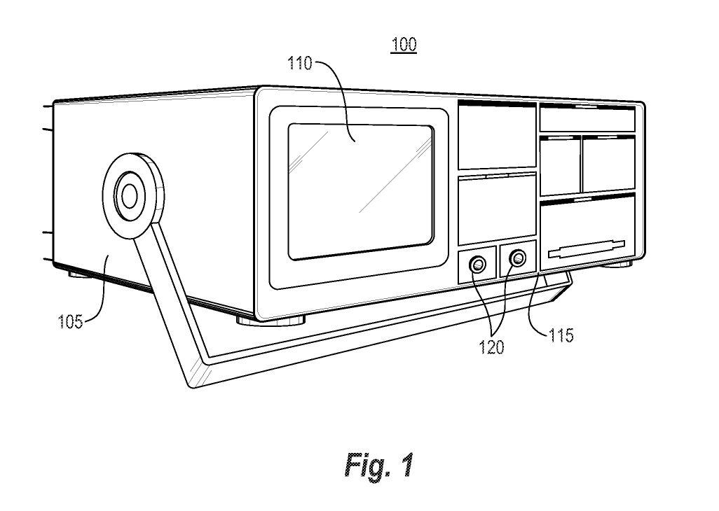

FIG. 1 is a diagram of an oscilloscope 100 according to an example embodiment. This example is provided to show the context in which certain oscilloscope probes may be used in accordance with various embodiments. The described embodiments are not limited, however, to specific types of oscilloscopes or oscilloscope features.

Referring to FIG. 1, oscilloscope 100 comprises a chassis 105, a display 110 occupying a left side of chassis 105, and a control interface 115 occupying a right side of chassis 105. Control interface 115 typically comprises various switches, knobs, or other interfaces for controlling the operation of oscilloscope 100 or initiating various functions. In addition, control interface 115 comprises probe connectors 120 for connecting one or more oscilloscope probes to oscilloscope 100. Probe connectors 120 can comprise, for instance, Bayonet Neill-Concelman (BNC) connectors or various other standardized connectors or custom connectors.

To operate oscilloscope 100, a user plugs an oscilloscope probe into one of probe connectors 120. The user then identifies a probe target on a circuit or device, and places a tip of the probe in contact with the probe target. If an electrical signal is apparent at the probe target, the probe transmits the signal from the probe tip to oscilloscope 100 via the attached probe connector 120. Oscilloscope 100 then processes the signal (e.g., to identify some signal characteristic) and displays the signal or signal characteristic on display 110. Example signal characteristics that can be displayed on display 110 include a root mean squared (RMS) voltage of the signal, a waveform of the signal, a frequency spectrum of the signal, and so on. In addition, oscilloscope 100 can perform various functions with respect to the transmitted signal, such as triggering on a specified event or stopping the waveform display in response to a user input. The oscilloscope can also be programmed to perform user-specified functions, or configured to adjust its display settings or functional characteristics.

Oscilloscope 100 is typically controlled using the controls provided in control interface 115. For example, a user may turn a knob or actuate a switch of control interface 115 to initiate a function or adjust the settings of oscilloscope 100. In addition to the controls on control interface 115, oscilloscope 100 can also be controlled by inputs from other sources. For example, oscilloscope 100 can be coupled to a foot pedal or a voice interface to allow the user to capture an oscilloscope trace at a particular moment.

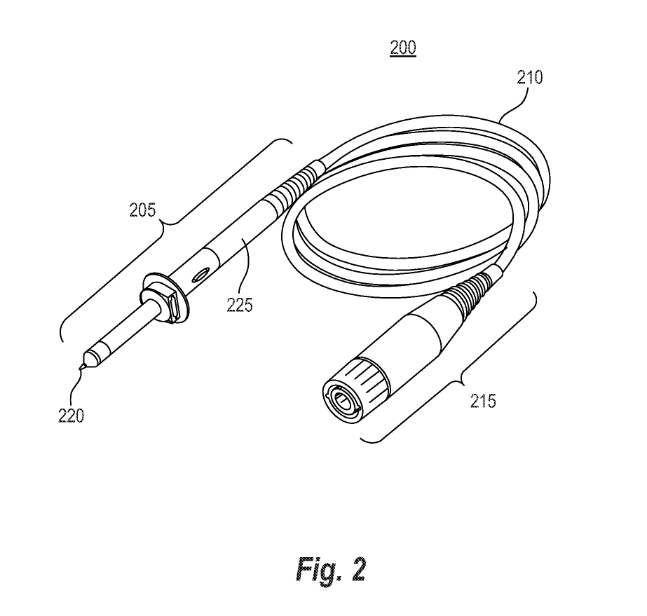

FIG. 2 is a diagram of an oscilloscope probe 200 according to an example embodiment. This example represents one type of oscilloscope probe that can be used in conjunction with an oscilloscope such as that illustrated in FIG. 1. However, it can be substituted with another type of oscilloscope probe or an oscilloscope probe having a different form factor.

Referring to FIG. 2, oscilloscope probe 200 comprises a probe head 205, a cable 210, and a pod 215. Probe head 205 comprises a probe tip 220 and a handle 225.

During operation, pod 215 is connected to an oscilloscope, and a user holds probe head 205 by handle 225. The user places probe tip 220 in contact with a probe target, and a signal apparent at the probe target is transmitted through cable 210 and pod 215 to the oscilloscope.

In some embodiments, probe head 205 and/or pod 215 can include components for processing the signal or for providing user input and/or output. For example, as will be described below, probe head 205 can include a status indicator and accompanying components to detect and indicate one or more characteristics of the signal apparent at the probe target, or to indicate a status of the oscilloscope. It can also include one or more buttons allowing a user to initiate a function of the oscilloscope. Similarly, pod 215 can include a logic circuit such as a user-configurable comparator for comparing the signal with a threshold voltage and then transmitting a control signal to the status indicator in probe head 205.

Where oscilloscope probe 200 is an active probe, probe head 205 typically comprises active components such as an active amplifier and signal conditioning circuitry. These active components and associated circuitry can be integrated with, or be implemented separate from, other components included in probe head 205, such as the status indicator. In one example, the same power source can be used to power both the active components and the status indicator.

Pod 215 typically comprises power conditioning circuitry and also communication hardware for interfacing with the oscilloscope. The communication hardware can be used to identify the probe to the oscilloscope, convey its characteristics and/or calibration factors, and define a signaling protocol for communication between the probe and the oscilloscope. In certain embodiments, this communication hardware can be modified to provide an interface and/or controller for a status indicator.

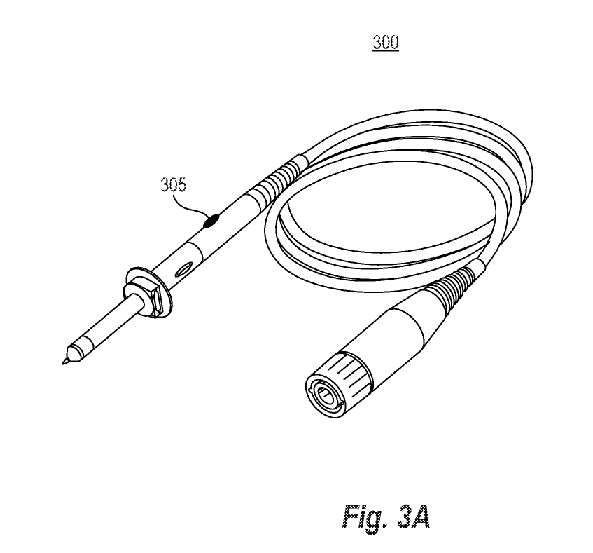

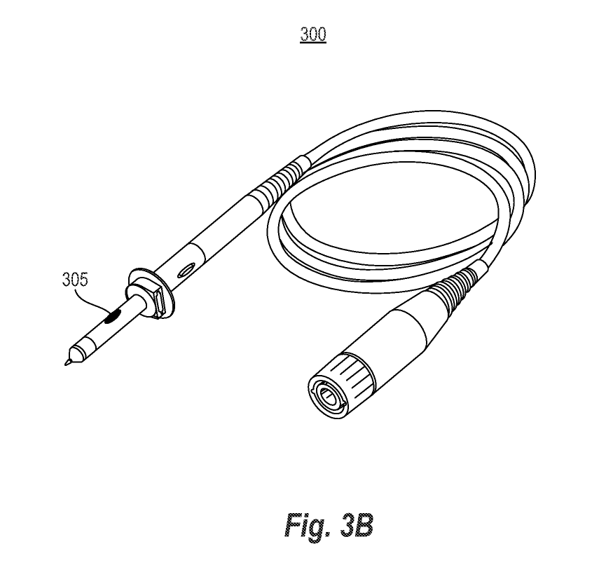

FIGS. 3A and 3B are diagrams of an oscilloscope probe 300 according to another example embodiment. These embodiments show one type of status indicator that can be attached to probe head 205 to indicate the characteristics of a signal detected by probe tip 220. The status indicator is placed at different locations in FIGS. 3A and 3B to illustrate that it is not limited to a specific place on the probe head.

Referring to FIGS. 3A and 3B, oscilloscope probe 300 is substantially the same as oscilloscope probe 200 of FIG. 2, except that oscilloscope probe 300 further comprises an LED 305 that functions as a status indicator to convey characteristics of a signal transmitted from probe tip 220 to the oscilloscope. For example, LED 305 can be illuminated to indicate that the signal is toggling, has RMS amplitude above a certain threshold, or contains certain frequency components. Similarly, LED 305 can be made to flash to indicate other characteristics of the signal.

As explained above with reference to FIG. 2, certain functions of a status indicator such as LED 305 can be implemented by circuits included in pod 215 and/or probe head 205. For example, pod 215 can include a comparator for determining whether the signal is above a user-defined threshold voltage, and then communicating with LED 305 to turn it on or off according to the comparison. In various alternative embodiments, LED 305 can be designed to be self-contained or it can communicate with the oscilloscope. Moreover, LED 305 can be used in connection with additional electronic components, such as a memory and logic circuits to implement functions more advanced than a simple comparator.

In general, the behavior of LED 305 can be user configurable. For example, a user can provide inputs through the oscilloscope to set a threshold voltage for a comparator in pod 215. Similarly, a user can provide inputs to configure other parameters, such as a particular signal characteristic to be monitored, a frequency range of interest, and so on. Such configurable parameters can be stored in various alternative locations of oscilloscope probe 300, such as in a memory within probe head 205 or pod 215.

As illustrated by FIGS. 3A and 3B, LED 305 can be mounted on different portions of probe head 205, such as the handle portion or a more distal portion. Additionally, in some embodiments, LED 305 can be mounted on a left side, a right side, or both sides of probe head 205 so that it can be visible to users who handle oscilloscope probe 300 with different hands. LED 305 can be conveniently mounted in a plastic housing of probe head 205, or it can be placed entirely on an external portion of probe head 205.

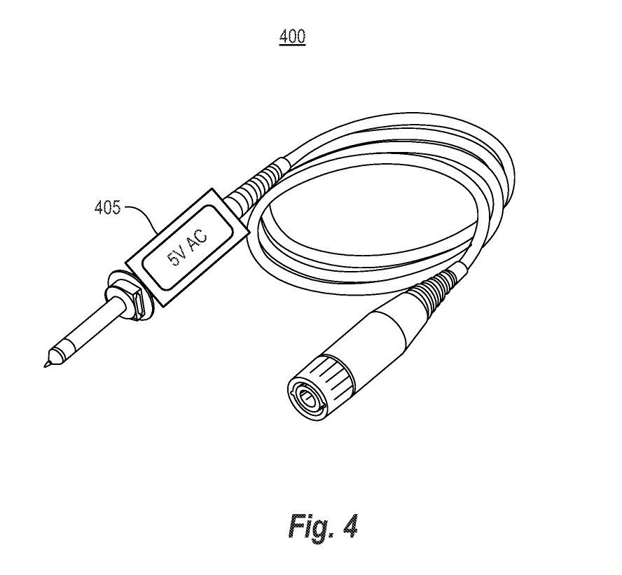

FIG. 4 is a diagram of an oscilloscope probe 400 according to still another example embodiment. This embodiment illustrates another type of status indicator that can be attached to probe head 205 to indicate the characteristics of a signal detected by probe tip 220.

Referring to FIG. 4, oscilloscope probe 400 is similar to oscilloscope probe 300 of FIGS. 3A and 3B, except that the status indicator takes the form of a display screen. In the embodiment of FIG. 4, the display screen is an LCD 405, but the LCD can be substituted with other types of displays in alternative embodiments.

LCD 405 can be used to display various types of information, including signal characteristics and oscilloscope characteristics. For example, in FIG. 4 it is shown displaying 5V AC, which represents the RMS voltage of an AC signal. Similarly, it could display other electrical characteristics, such as frequency, DC magnitude, peak-to-peak voltage, and so on. Alternatively, LCD 405 could display status information related to the oscilloscope, such as whether it is awaiting a trigger or has been triggered.

To facilitate user interactions with the oscilloscope, oscilloscope probe 400 can further comprise an interface such as a button or switch for initiating one or more functions of the oscilloscope. Such an interface can be located on any portion of probe head 205, but it is typically located on the handle for convenient operation. During typical operation, the user may inspect LCD 405 to identify a particular event or signal characteristic, and upon identifying such an event, the user may actuate the button or other interface to stop the oscilloscope display and analyze the captured measurements. This combination of features provides user convenience by allowing the user to take measurements without looking back and forth at the oscilloscope.

In certain embodiments, two-way communication can be provided between the oscilloscope and LCD 405 or an alternative display screen. This two-way communication could be implemented, for example, by an I²C bus connected between LCD 405 and the oscilloscope. Such two-way communication can allow LCD 405 to take advantage of processing components within the oscilloscope and display the results of such processing. For example, LCD 405 could display measurements obtained through signal processing algorithms implemented in hardware and/or software within oscilloscope 100 of FIG. 1.

Oscilloscope probe 400 can further comprise a button or some other interface to allow user interaction with LCD 405 and/or the oscilloscope. Such a button can be used, for example, to initiate functions of the oscilloscope, or it can be used to control LCD 405. One way for a user to control LCD 405, for instance, is by pressing the button to cycle through different display modes corresponding to different measurements. For example, different display modes can be used to display RMS voltage, peak-to-peak voltage, frequency, and so on. Moreover, the different display modes can be linked to different processing operations of the oscilloscope, such that when the user changes the display mode of LCD 405, a control signal is also sent to the oscilloscope to change measurement information sent to LCD 405 from the oscilloscope.

The location, orientation, and other aspects of LCD 405 as shown in FIG. 4 are merely presented as one example of how to configure a display screen on a probe head. However, these and other aspects of LCD 405 or an alternative display screen can be modified in other embodiments.

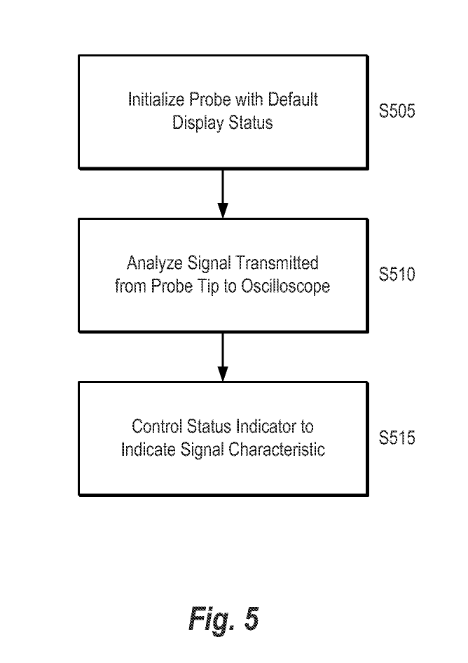

FIG. 5 is a flowchart illustrating a method of operating an oscilloscope probe according to an example embodiment. For convenience of explanation, it will be assumed that the method of FIG. 5 is performed using oscilloscope probe 300 or 400 in combination with oscilloscope 100. However, the method can be applied to other types of oscilloscope probes and oscilloscopes. In the description that follows, example method steps will be indicated by parentheses (SXXX).

Referring to FIG. 5, the method begins by initializing the oscilloscope probe with a default display status upon connection of the probe to an oscilloscope (S505). The default display status can be, for instance, a message on an LCD such as “connected successfully” or “waiting for signal”. For an LED, on the other hand, the default display status could be a flashing state to indicate that communication with the oscilloscope has been established.

Next, the method analyzes a signal transmitted from probe tip 220 to oscilloscope 100 to determine at least one characteristic of the signal (S510). As described with reference to FIGS. 3 and 4, this analysis can be performed in a variety of ways, such as comparing the signal with a user-defined threshold value within pod 215, or processing the signal in hardware and/or hardware within oscilloscope 100. In addition, the at least one signal characteristic can be one of various standard signal parameters, such as its amplitude, RMS voltage, frequency, and so on. Alternatively, it can be a non-standard parameter, such as a user-defined quantity defined by a user.

Next, the method controls a status indicator located on probe head 205 to indicate the at least one characteristic to a user (S515). The status indicator can be one of those described above with reference to FIGS. 3 and 4, and it can be controlled by one of various methods described above. In addition, as described with reference to FIGS. 3 and 4, the status indicator can be used in conjunction with a user interface such as a switch, which can perform a function such as transmitting a control signal to a display screen to change its display mode, or transmitting a control signal to oscilloscope 100 to initiating an oscilloscope function. Similarly, the status indicator can be used in conjunction with other types of user input mechanisms such as a foot pedal or voice command system for initiating a stop function or other oscilloscope function.

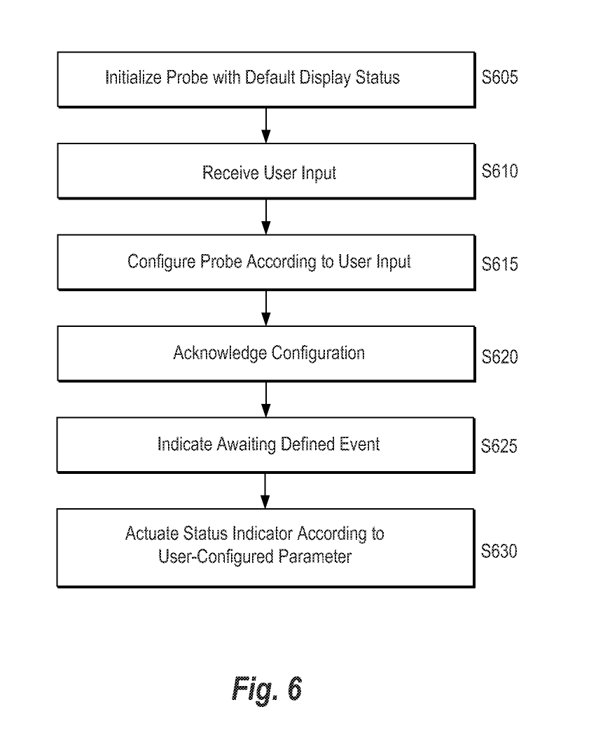

FIG. 6 is a flowchart illustrating a method of operating an oscilloscope probe according to another example embodiment. The method of FIG. 6 implements one form of user configuration as described above with reference to FIGS. 3 and 4. Like the method of FIG. 5, the method of FIG. 6 will also be described with reference to oscilloscope probe 300 or 400 and oscilloscope 100. However, the method can be applied to other types of oscilloscope probes and oscilloscopes.

Referring to FIG. 6, the method begins by initializing the oscilloscope probe with a default display status upon connection of the probe to an oscilloscope (S605). Similar to the method of FIG. 5, the default display status can be, for instance, a message on an LCD such as “connected successfully” or “waiting for signal”. For an LED, on the other hand, the default display status could be a flashing state to indicate that communication with the oscilloscope has been established.

Next, the method receives a user input such as a value of a configurable parameter (S610). The user input can be received by either oscilloscope probe 300 or 400 or the oscilloscope itself. Next, the user input is used to configure oscilloscope probe 300 or 400, or oscilloscope 100 (S615). This configuration can be performed, for example, by using the user input value to modify a configurable element such as a comparator in pod 215, or a multimeter chip or other processing element in oscilloscope 100.

After the oscilloscope probe is configured, the probe or the oscilloscope can acknowledge the configuration, for instance, by indicating that they are ready for operation (S620). Then, the status indicator signals that it is waiting for an event of interest to occur so it can do its job (S625). For example, the LCD might display a message such as “no signal detected” if not yet connected or “awaiting threshold” if the signal has not passed through a user-defined threshold.

Finally, during operation of oscilloscope probe 300 or 400, or oscilloscope 100, the status indicator is actuated according to user-configured parameter (S630). For example, if the signal is above a user-defined threshold voltage used to configure the comparator, LED 305 can be turned on.

While example embodiments are disclosed herein, one of ordinary skill in the art appreciates that many variations that are in accordance with the present teachings are possible and remain within the scope of the appended claims. The invention therefore is not to be restricted except within the scope of the appended claims.

What is claimed is:

1. A system, comprising:
an oscilloscope probe comprising a probe head having a probe tip and configured to transmit a signal from the probe tip to an oscilloscope; and
a status indicator located on the probe head and configured to convey information to a user to indicate at least one characteristic of the signal.

2. The system of claim 1, wherein the at least one characteristic of the signal comprises whether the signal is toggling or whether the signal is a direct current voltage above a predetermined threshold.

3. The system of claim 1, wherein the status indicator comprises a light that turns on or off to indicate the at least one characteristic of the signal.

4. The system of claim 3, wherein the light flashes to indicate that the signal has a first characteristic, and maintains a persistent “on” state to indicate that the signal has a second characteristic.

5. The system of claim 1, further comprising a comparator located in the oscilloscope probe, wherein the comparator compares the signal against a predetermined criterion and communicates with the status indicator to indicate that the signal meets the criterion.

6. The system of claim 5, wherein the predetermined criterion is whether the signal has an amplitude above a user-defined threshold.

7. The system of claim 5, wherein the oscilloscope probe further comprises a pod and a cable connected between the probe head and the pod, and wherein the comparator is coupled to the pod.

8. The system of claim 1, wherein the status indicator comprises a display screen that presents graphical information indicating the at least one characteristic of the signal.

9. The system of claim 8, wherein the display screen comprises a liquid crystal display.

10. The system of claim 8, further comprising a multimeter chip coupled to the display screen and configured to generate multimeter measurements of the signal and provide the multimeter measurements to the display screen for graphical display.

11. The system of claim 8, further comprising a switch connected to the probe head and configured to control a display mode of the display screen in response to user interaction.

12. The system of claim 1, further comprising a switch connected to the probe head and configured to initiate a function of the oscilloscope in response to user interaction.

13. The system of claim 12, wherein the function is a stop function of the oscilloscope.

14. The system of claim 1, wherein the status indicator is further configured to indicate at least one characteristic of the oscilloscope.

15. The system of claim 14, wherein the at least one characteristic of the oscilloscope comprises whether the oscilloscope is running, whether the oscilloscope is stopped, or whether the oscilloscope is awaiting a trigger.

16. A method of operating an oscilloscope probe comprising a probe head having a probe tip and configured to transmit a signal from the probe tip to an oscilloscope, the method comprising:
analyzing the signal to determine at least one characteristic of the signal; and
controlling a status indicator located on the probe head to indicate the at least one characteristic to a user.

17. The method of claim 16, wherein the status indicator comprises a light, and controlling the status indicator comprises turning on the light to indicate that the signal is an alternating current signal within a predetermined frequency range.

18. The method of claim 16, wherein the status indicator comprises a display screen, and controlling the status indicator comprises generating a measurement related to the signal and presenting the measurement in a graphical form on the display screen.

19. The method of claim 18, further comprising:
receiving a control signal from a switch located on the probe head, and modifying a display mode of the display screen in response to the control signal.

20. The method of claim 16, further comprising:
receiving a control signal from a switch located on the probe head, and initiating a function of the oscilloscope in response to the control signal.
